(19) United States
(12) Patent Application Publication
(10) Pub. No.: US 2025/0248308 A1
(43) Pub. Date: Jul. 31, 2025

(54) PIEZOELECTRIC DEVICE, ULTRASONIC TRANSDUCER, MICRO-ELECTROMECHANICAL DEVICE AND METHOD OF FORMING A PIEZOELECTRIC DEVICE

(71) Applicant: Infineon Technologies AG, Neubiberg (DE)

(72) Inventors: Mohanraj SOUNDARA PANDIAN, Unterschleißheim (DE); Malika BELLA, Ottobrunn (DE); Thomas STANGL, Regen (DE); Robert GRÜNBERGER, Nandlstadt (DE); Thomas BEVER, München (DE); Stephan Gerhard ALBERT, München (DE); Stefan LIPPS, Wenzenbach (DE)

(21) Appl. No.: 19/016,318

(22) Filed: Jan. 10, 2025

(30) Foreign Application Priority Data
Jan. 26, 2024 (DE) 102024200711.0

(51) Int. Cl. H10N 30/87; H10N 30/06; H10N 30/074; H10N 30/853

(52) U.S. Cl. CPC H10N 30/872; H10N 30/06; H10N 30/074; H10N 30/853

(57) ABSTRACT

Provided is a piezoelectric device. The piezoelectric device includes a piezoelectric layer including a first surface and a second surface opposing each other. Furthermore, the piezoelectric device includes a first electrode formed on the first surface and a second electrode formed on the second surface. The piezoelectric device includes a dielectric material enclosing the piezoelectric layer. Additionally, the piezoelectric device includes a first interconnect electrically coupled to the first electrode and a second interconnect electrically coupled to the second electrode. The first electrode is arranged between the piezoelectric layer and each of the first interconnect and the second interconnect. The first interconnect and the second interconnect are arranged distant to the first electrode.

### CROSS-REFERENCE TO RELATED APPLICATION

This application claims priority to Germany patent application no. 102024200711.0 filed on Jan. 26, 2024, the content of which is incorporated by reference herein in its entirety.

### TECHNICAL FIELD

The present disclosure relates to piezoelectric structures. In particular, examples of the present disclosure relate to a piezoelectric device, an ultrasonic transducer, a micro-electromechanical device and a method of forming a piezoelectric device.

### BACKGROUND

Thin film piezoceramics are used in a variety of Micro-Electro-Mechanical Systems (MEMS) devices likes resonators, actuators, ultrasonic transducers or sensors. Highly doped piezoceramics are gaining more attention due to their improved piezoelectric modulus d₃₃. The doping of the piezoceramics causes problems during process integration. For example, typical dopants are highly resistant to dry etching and show a poor selectivity to surrounding layers in a layer stack. On the other hand, typical dopants leave residues on the surface in case of wet etching. Furthermore, leakage paths along surfaces and sidewalls of the piezoceramic in conventional architectures may lead to device breakdown.

Hence, there may be a demand for improved piezoelectric structures.

### SUMMARY

This demand is met by the subject-matter of the independent claims. Advantageous embodiments are addressed by the dependent claims.

According to a first aspect, the present disclosure provides a piezoelectric device. The piezoelectric device includes a piezoelectric layer including a first surface and a second surface opposing each other. Furthermore, the piezoelectric device includes a first electrode formed on the first surface and a second electrode formed on the second surface. The piezoelectric device includes a dielectric material enclosing the piezoelectric layer. Additionally, the piezoelectric device includes a first interconnect electrically coupled to the first electrode and a second interconnect electrically coupled to the second electrode. The first electrode is arranged between the piezoelectric layer and each of the first interconnect and the second interconnect. The first interconnect and the second interconnect are arranged distant to the first electrode.

According to a second aspect, the present disclosure provides an ultrasonic transducer including the piezoelectric device according to the first aspect. A recess is formed in the dielectric material such that part of the dielectric material forms a diaphragm embedding the piezoelectric layer.

According to a third aspect, the present disclosure provides a micro-electromechanical device including a micromirror and a spring structure supporting the micromirror. The spring structure includes at least one piezoelectric device according to the first aspect.

According to a fourth aspect, the present disclosure provides method of forming a piezoelectric device. The method includes forming a piezoelectric layer including a first surface and a second surface opposing each other. Furthermore, the method includes forming a first electrode on the first surface and forming a second electrode on the second surface. The method includes forming a dielectric material enclosing the piezoelectric layer. Additionally, the method includes forming a first interconnect electrically coupled to the first electrode and forming a second interconnect electrically coupled to the second electrode. The first electrode is arranged between piezoelectric layer and each of the first interconnect and the second interconnect. The first interconnect and the second interconnect are arranged distant to the first electrode.

According to the proposed technique, the contacts to the electrodes may be formed without exposure of the piezoelectric layer to any etchants. Furthermore, the sidewalls and surfaces of the piezoelectric layer are insulated by dielectric material to avoid or at least minimize electrical leakage paths.

### BRIEF DESCRIPTION OF THE DRAWINGS

Some examples of apparatuses and/or methods will be described in the following by way of example only, and with reference to the accompanying figures, in which:

FIG. 1 illustrates an example of a piezoelectric device;

FIG. 2 illustrates an example of an ultrasonic transducer;

FIG. 3 illustrates an example of a micro-electromechanical device;

FIG. 4 illustrates an example of a method of forming a piezoelectric device; and

FIGS. 5A-5P illustrate an exemplary piezoelectric device during various steps of its manufacture.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

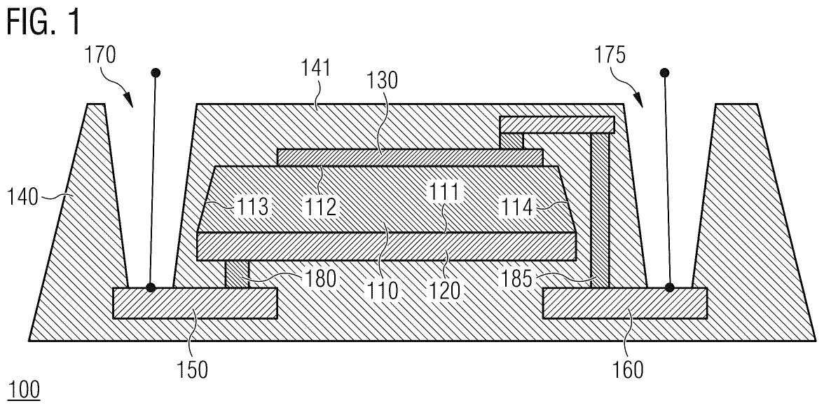

FIG. 1 illustrates sectional view of an exemplary piezoelectric device 100.

The piezoelectric device 100 comprises a piezoelectric layer 110. The piezoelectric layer 110 comprises a first surface 111 and a second surface 112 opposing each other. The first surface 111 and the second surface 112 follow each other along a thickness direction of the piezoelectric layer 110 (and the piezoelectric device 100). The first surface 111 and the second surface 112 may be (substantially) parallel to each other as shown in FIG. 1. The first surface 111 and the second surface 112 may be (substantially) plane (flat) surfaces. The piezoelectric layer 110 further comprises sidewalls 113 and 114 opposing each other. The sidewalls 113 and 114 laterally limit the piezoelectric layer 110. The sidewalls 113 and 114 connect the first surface 111 and the second surface 112. The first surface 111 and the second surface 112 may exhibit any suitable (target) dimensions. Similarly, the thickness of the piezoelectric layer 110 (i.e., the vertical distance between the first surface 111 and the second surface 112) is generally not limited. For example, the piezoelectric layer 110 may be a thin film. In other words, a thickness of the piezoelectric layer 110 may at least 0.1 μm, 0.5 μm or 1 μm. The thickness of the piezoelectric layer 110 may be at maximum 1 μm, 3 μm, 5 μm or 10 μm.

The piezoelectric layer 110 comprises a piezoelectric material such as one or more of Aluminum Nitride (AlN), Quartz (SiO₂), Lead Zirconate Titanate (PZT), Polyvinylidene Fluoride (PVDF), Barium Titanate (BaTiO₃), Lithium Niobate (LiNbO₃) and Gallium Orthophosphate (GaPO₄). However, it is to be noted that the present disclosure is not limited to the aforementioned materials. Other piezoelectric materials may be used instead or in addition. According to examples, the piezoelectric layer 110 may comprise or be a doped piezoelectric material. The piezoelectric material may be lightly or be highly doped. For example, an atomic ratio of dopants in the doped piezoelectric material may be at least 1%, 5%, 10%, 15%, 20% 25% or 30%. The atomic ratio of dopants in a doped piezoelectric material refers to the ratio of atoms of the dopant element(s) to the atoms of the primary constituent(s) of the piezoelectric material. For a highly-doped piezoelectric material, the atomic ratio of dopants in the doped piezoelectric material may be up to 50%, 55%, 60%, 65%, 70% or 75%. Various dopants (dopant materials) such as one or more of Scandium (Sc), Chromium (Cr), Titanium (Ti), Hafnium (Hf), Tantalum (Ta), Molybdenum (Mo), Niobium (Nb), Yttrium (Y) and Zirconium (Zr) may be used. However, it is to be noted that the present disclosure is not limited to the aforementioned materials. Other dopants may be used instead or in addition. Particularly, the doped piezoelectric material may be Sc-doped AlN with an atomic ratio of Sc dopants in the doped AlN of at least 20% and at maximum 60%.

Furthermore, the piezoelectric device 100 comprises a first electrode 120 (directly) formed on the first surface 111 of the piezoelectric layer 110 and a second electrode 130 (directly) formed on the second surface 112 of the piezoelectric layer 110. Each of the first electrode 120 and the second electrode 130 is formed of one or more electrically conductive materials such as one or more metals. For example, the first electrode 120 and the second electrode 130 may comprise one or more of Tungsten (W), Copper (Cu), Titanium (Ti), Titanium Nitride (TiN), Aluminum (Al) and Platinum (Pt). However, it is to be noted that the present disclosure is not limited to the aforementioned materials. Other electrically conductive materials may be used instead or in addition. The first electrode 120 and the second electrode 130 may be made from the same material(s) or from different materials. The first electrode 120 may partially cover the first surface 111 as illustrated in FIG. 1. In alternative examples, the first electrode 120 may entirely cover the first surface 111. The second electrode 130 may entirely cover the second surface 112 as illustrated in FIG. 1. In alternative examples, second electrode 130 may partially cover the second surface 112. The thicknesses of the first electrode 120 and the second electrode 130 are generally not limited. For example, the respective thickness of the first electrode 120 and the second electrode 130 may be at least 1 nm, 10 nm, 20 nm, 50 nm or 100 nm. On the other hand, the respective thickness of the first electrode 120 and the second electrode 130 may be at maximum 500 nm, 250 nm, 100 nm or 50 nm. The first electrode 120 and the second electrode 130 may exhibit the same thickness or different thicknesses. The first electrode 120 and the second electrode 130 are provided for electrically contacting the piezoelectric layer 110. The first electrode 120 and the second electrode 130 allow to provide an electrical potential (i.e., a voltage) to the piezoelectric layer 110 for controlled (and reversible) deformation of the piezoelectric layer 110 due to the piezoelectric effect. Analogously, the first electrode 120 and the second electrode 130 allow to measure an electrical potential (i.e., a voltage) caused in the piezoelectric layer 110 due to the piezoelectric effect by a deformation of the piezoelectric layer 110.

The piezoelectric device 100 comprises a dielectric material 140 enclosing the piezoelectric layer 110. The dielectric material 140 further encloses the first electrode 120 and the second electrode 130. In other words, the piezoelectric layer 110 as well as the first electrode 120 and the second electrode 130 are fully embedded in the dielectric material 140. For example, the dielectric material 140 may be one or more of Silicon dioxide (SiO₂) and Silicon Nitride (Si₃N₄). However, it is to be noted that the present disclosure is not limited to the aforementioned materials. Other dielectric materials may be used instead or in addition. The dielectric material 140 provides electrical insulation for the piezoelectric layer 110 as well as the first electrode 120 and the second electrode 130.

Additionally, the piezoelectric device 100 comprises a first interconnect 150 electrically coupled to the first electrode 120 and a second interconnect 160 electrically coupled to the second electrode 130. The first interconnect 150 and the second interconnect 160 allow to electrically contact the electrodes 120 and 130 and, hence, the piezoelectric layer 110 from external (i.e., from outside the piezoelectric device 100). In the example of FIG. 1, the first interconnect 150 and the second interconnect 160 are both arranged below the stack formed by the piezoelectric layer 110 and the electrodes 120 and 130. In more general terms, the first interconnect 150 and the second interconnect 160 are both arranged on the same side relative to the stack formed by the piezoelectric layer 110 and the electrodes 120 and 130. In other words, the first electrode 120 is arranged between the piezoelectric layer 110 and each of the first interconnect 150 and the second interconnect 160. The first interconnect 150 and the second interconnect 160 are arranged distant (at a distance) to the first electrode 120 (along the thickness direction of the piezoelectric device 100). The vertical distance of the first interconnect 150 to the first electrode 120 is smaller than the vertical distance of the first interconnect 150 to the second electrode 130. Analogously, the vertical distance of the second interconnect 160 to the first electrode 120 is smaller than the vertical distance of the second interconnect 160 to the second electrode 130.

The thicknesses of the first interconnect 150 and the second interconnect 160 are generally not limited. For example, the respective thickness of the first interconnect 150 and the second interconnect 160 may be at least 10 nm, 20 nm, 50 nm, 100 nm 250 nm or 500. On the other hand, the respective thickness of the first electrode 120 and the second electrode 130 may be at maximum 3 μm, 2 μm, 1.5 μm, 1 μm, 750 nm, 500 nm, 250 nm, 100 nm or 50 nm. The thickness of the first electrode 120 and the second electrode 130 may be chosen to accommodate for facilitating or enabling wirebonding or similar post assembly processes.

Also the first interconnect 150 and the second interconnect 160 are arranged in the dielectric material 140. The dielectric material 140 encloses both the first interconnect 150 and the second interconnect 160 in part. The first interconnect 150 is accessible (e.g., exposed) from the outside via a first opening (recess) 170 formed in the dielectric material 140. The second interconnect 160 is accessible (e.g., exposed) from the outside via a second opening 175 formed in the dielectric material 140. The first opening 170 extends from a surface 141 of the dielectric material 140 to the first interconnect 150. The second opening extends from the surface 141 of the dielectric material 140 to the second interconnect 160. In the example of FIG. 1, the surface 141 of the dielectric material 140 is the top surface of the dielectric material 140 such that the surface 141 of the dielectric material 140 and the interconnects 150 and 160 are arranged on opposite sides of the stack formed by the piezoelectric layer 110 and the electrodes 120 and 130. In other words, the second electrode 130 is arranged between the second surface 112 of the piezoelectric layer 110 and the surface 141 of the dielectric material 140. The first opening 170 and the second opening 175 extend laterally offset to the dielectric layer 140 and along the thickness direction of the piezoelectric device 100.

In the example of FIG. 1, the first opening 170 and the second opening 175 both taper from the surface 141 of the dielectric material 140 to the respective interconnect 150 and 160. However, it is to be noted that the present limited thereto. Other geometries may be used instead for the first opening 170 and the second opening 175.

As described above, the first interconnect 150 is electrically coupled to the first electrode 120. A first electrically conductive path 180 is formed in the dielectric material 140 between the first electrode 120 and the first interconnect 150 for electrically coupling the first interconnect 150 to the first electrode 120. Analogously, a second electrically conductive path 185 is formed in the dielectric material 140 between the second electrode 130 and the second interconnect 160 for electrically coupling the second interconnect 160 to the second electrode 130. The dielectric material 140 separates, i.e., electrically insulates, the piezoelectric layer 110 from the electrically conductive paths 180 and 185. Each of the first electrically conductive path 180 and the second electrically conductive path 185 is formed of one or more electrically conductive materials such as one or more metals. For example, the first electrically conductive path 180 and the second electrically conductive path 185 may comprise one or more of Al, W, Cu, Pt or doped polysilicon (polycrystalline silicon). However, it is to be noted that the present disclosure is not limited to the aforementioned materials. Other electrically conductive materials may be used instead or in addition. The geometries of the first electrically conductive path 180 and the second electrically conductive path 185 illustrated in FIG. 1 are for illustrative purposes only. In other examples, the first electrically conductive path 180 and the second electrically conductive path 185 may exhibit different geometries (routings in the dielectric material 140).

The structures for contacting the electrodes 120 and 130, i.e., the interconnects 150 and 160 as well as the electrically conductive paths 180 and 185, may be formed without exposure of the piezoelectric layer 110 to any etchants. This is particularly favorable in case the piezoelectric layer 110 comprises a highly doped piezoelectric material as typical dopants are highly resistant to dry etching and show a poor selectivity to surrounding layers in a layer stack. Furthermore, typical dopants leave residues on the surface in case of wet etching. Furthermore, the sidewalls 113 and 114 as well as the surfaces 111 and 112 of the piezoelectric layer 110 are electrically insulated by the dielectric material 140 to avoid or at least minimize electrical leakage paths. Accordingly, breakdown of the piezoelectric device 100 may be avoided.

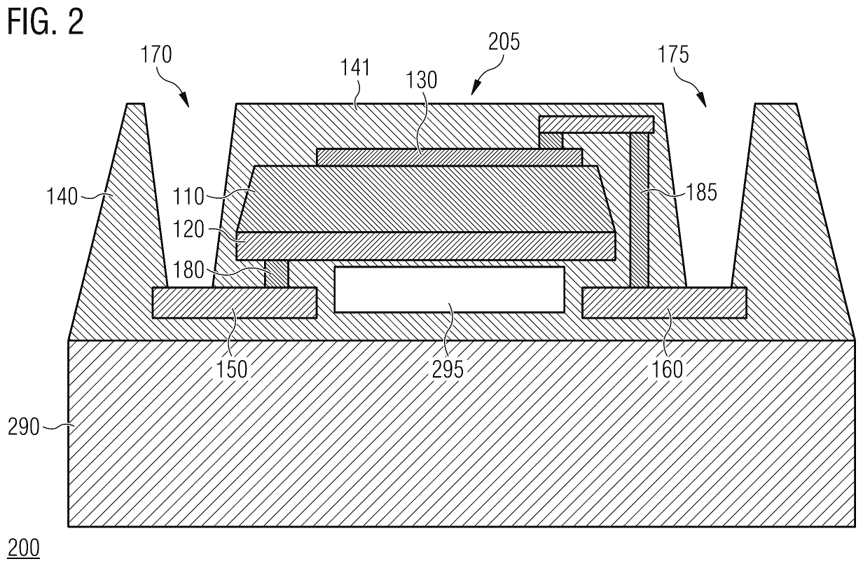

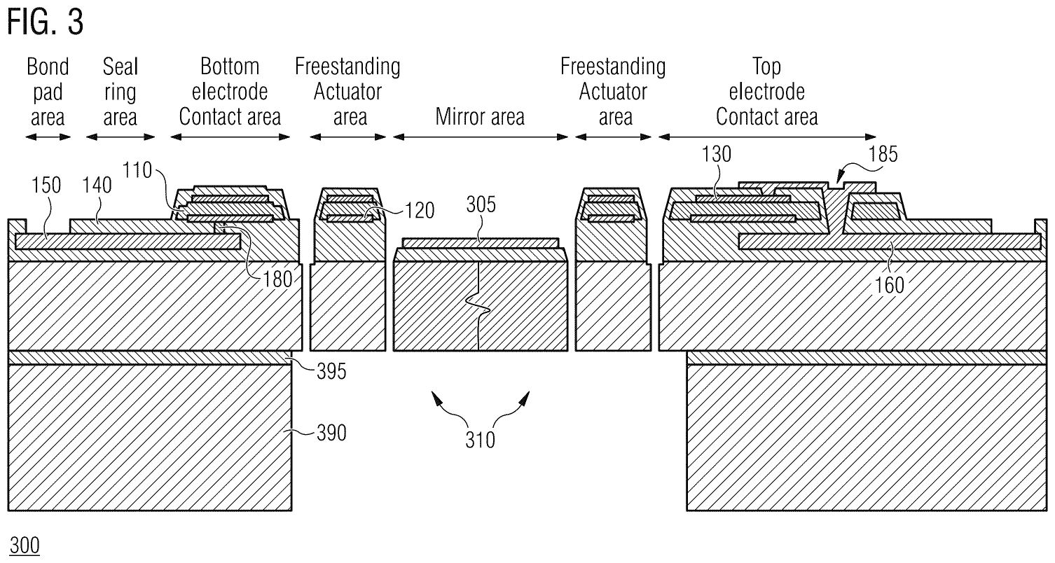

The piezoelectric device 100 may be used in various applications due to its advantageous properties. Two exemplary applications will be described in the following with reference to FIG. 2 and FIG. 3. However, it is to be noted that the piezoelectric device 100 is not limited to the exemplary applications described in the following.

FIG. 2 illustrates a sectional view of an exemplary ultrasonic transducer 200. The ultrasonic transducer 200 may be micro-electromechanical device. In particular, the ultrasonic transducer 200 may be a Piezoelectric Micromachined Ultrasonic Transducer (PMUT). The ultrasonic transducer 200 comprises the piezoelectric device 100 as described above. The piezoelectric device 100 is formed on a carrier substrate 290 such as a silicon substrate.

A recess (opening) 295 is formed in the dielectric material 140 such that part of the dielectric material 140 forms a diaphragm 205 embedding the piezoelectric layer 110 (together with the electrodes 120 and 130). In particular, the part of the dielectric material 140 above the recess 295 forms the diaphragm 205. The recess 295 is formed below the piezoelectric layer 110 and the first electrode 120. In other words, the recess 295 is formed distant to the first electrode 120. The first electrode 120 is arranged between the piezoelectric layer 110 and the recess 295. The recess 295 is formed laterally between the first interconnect 150 and the second interconnect 160. The recess 295 may be filled with air or any other suitable gas. Alternatively, the recess 295 may hold a vacuum.

As described above for the piezoelectric device 100, the first interconnect 150 and the second interconnect 160 allow to electrically contact the electrodes 120 and 130 and, hence, the piezoelectric layer 110 from external (i.e., from outside the piezoelectric device 100). Accordingly, the piezoelectric layer 110 may be used to generate ultrasonic waves based on an externally provided drive signal and/or be used to generate a measurement signal based on received (measured) ultrasonic waves. For example, the piezoelectric device 110 may be configured to deform the diaphragm 205 based on an electrical signal received at the first and the second interconnect 150, 160 to emit ultrasonic waves. Alternatively or additionally, the piezoelectric device 110 may be configured to output a respective measurement signal at the first and the second interconnect 150, 160 based on a deformation of the diaphragm 205 caused by received ultrasonic waves.

The ultrasonic transducer 200 may be configured to emit and/or detect ultrasonic waves at least between 20 kHz and 1 GHz and/or any sub-range thereof. In particular, the ultrasonic transducer 200 may be configured to emit and/or detect low frequency ultrasonic waves (e.g., at approx. 50 kHz) for applications in air such as proximity detection (e.g., for parking sensors of vehicles) or high frequency ultrasonic waves (e.g., at approx. 2 to 10 MHz) for diagnostics applications (e.g., medical ultrasound).

FIG. 3 illustrates a sectional view of an exemplary micro-electromechanical device 300.

The micro-electromechanical device 300 comprises a micromirror 305. The dimensions of the micromirror 305 may, e.g., be in the order of micrometers. A spring structure 310 of the micro-electromechanical device 300 supports the micromirror 305. The spring structure 310 comprises a freestanding actuator area and a bottom electrode (first electrode) contact area as illustrated in FIG. 1. The micromirror 305 is movable relative to the rest of the micro-electromechanical device 300 via the spring structure 310. As indicated in FIG. 3, the spring structure 310 comprises a piezoelectric device according to the proposed technique. Optionally, the spring structure 310 may comprise plural piezoelectric devices according to the proposed technique.

As described above for the piezoelectric device 100, the first interconnect 150 and the second interconnect 160 allow to electrically contact the electrodes 120 and 130 and, hence, the piezoelectric layer 110 from external (i.e., from outside the piezoelectric device 100). Accordingly, the piezoelectric layer 110 may be used to move the micromirror 305 based on an externally provided drive signal and/or be used to generate a measurement signal based on a motion and/or position of the micromirror 305 (as the motion/position of the micromirror 305 causes a deformation of the spring structure 310 measurable via the piezoelectric layer 110). For example, the piezoelectric device 110 may be configured to deform the spring structure 310 based on an electrical signal received at the first and the second interconnect 150, 160 to deform the spring structure 310 for deflecting the micromirror 305. Alternatively or additionally, the piezoelectric device 110 may be configured to output a respective measurement signal at the first and the second interconnect 150, 160 based on a deflection of the micromirror 305.

The micro-electromechanical device 300 comprises a carrier substrate 390 such as a silicon substrate for holding the remaining elements of the micro-electromechanical device 300. One or more layers or elements such as the buried oxide layer 395 may additionally be formed in the carrier substrate 390.

The above description focused on the proposed piezoelectric device and its applications. The following sections of the description will focus on the manufacturing of the proposed piezoelectric device.

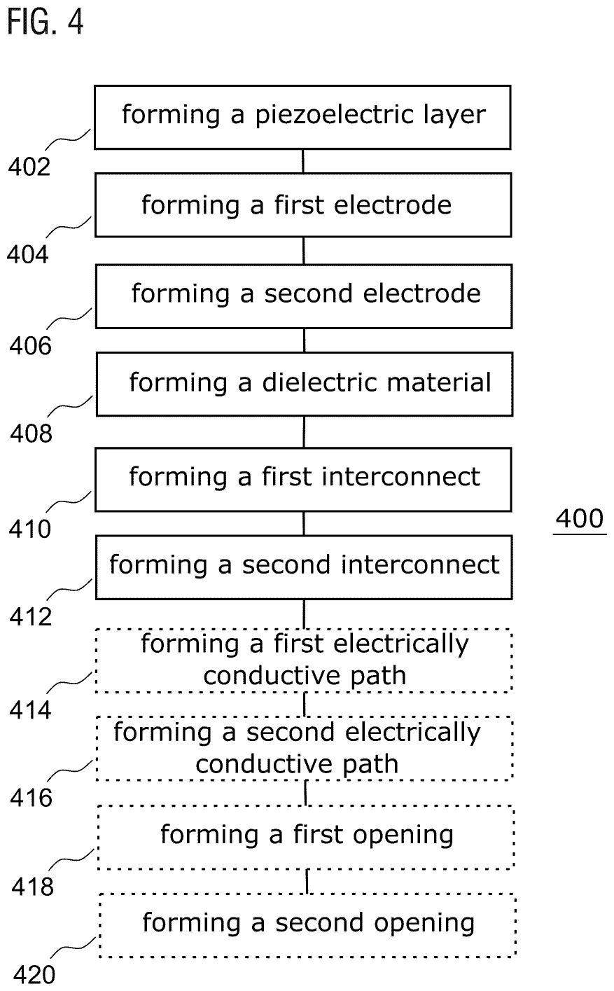

FIG. 4 illustrates a flowchart of an exemplary method 400 of forming a piezoelectric device.

The method 400 comprises forming 402 a piezoelectric layer comprising a first surface and a second surface opposing each other. For example, forming 402 the piezoelectric layer may comprise depositing a doped piezoelectric material. The atomic ratio of dopants in the doped piezoelectric material may be at least 20% for highly-doped piezoelectric materials—as described above for the piezoelectric device 100. Furthermore, the method 400 comprises forming 404 a first electrode on the first surface and forming 406 a second electrode on the second surface. The method 400 comprises forming 408 a dielectric material enclosing the piezoelectric layer. Additionally, the method 400 comprises forming 410 a first interconnect electrically coupled to the first electrode and forming 412 a second interconnect electrically coupled to the second electrode. The first electrode is arranged between piezoelectric layer and each of the first interconnect and the second interconnect. The first interconnect and the second interconnect are arranged distant to the first electrode.

The method 400 allows to provide a piezoelectric device as described above. More details and aspects of the method 400 are explained in connection with the proposed technique or one or more example described above or below. The method 400 may comprise one or more additional optional features corresponding to one or more aspects of the proposed technique, or one or more example described above or below.

For example, the method 400 may further comprise forming 414 a first electrically conductive path in the dielectric material between the first electrode and the first interconnect for electrically coupling the first interconnect to the first electrode. Analogously, the method 400 may further comprise forming 416 a second electrically conductive path in the dielectric material between the second electrode and the second interconnect for electrically coupling the second interconnect to the second electrode. The forming of the first and second electrically conductive paths in the dielectric material allows to couple the first and second interconnects with the respective one of the first electrode and the second electrode.

Alternatively or additionally, the method 400 may further comprise forming 418 a first opening in the dielectric material. The first opening extends from a surface of the dielectric material to the first interconnect. Analogously, the method 400 may further comprise forming 420 a second opening in the dielectric material. The second opening extends from the surface of the dielectric material to the second interconnect. The second electrode is arranged between the second surface of the piezoelectric layer and the surface of the dielectric material—as described above for the piezoelectric device 100. The first and second openings allow to access the first and second interconnects from outside for electrically contacting the piezoelectric layer.

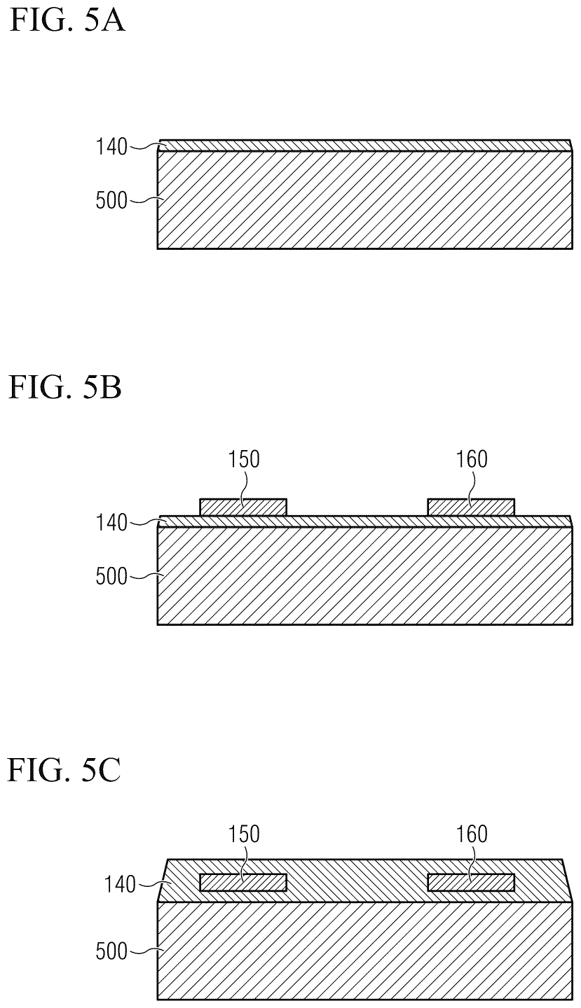

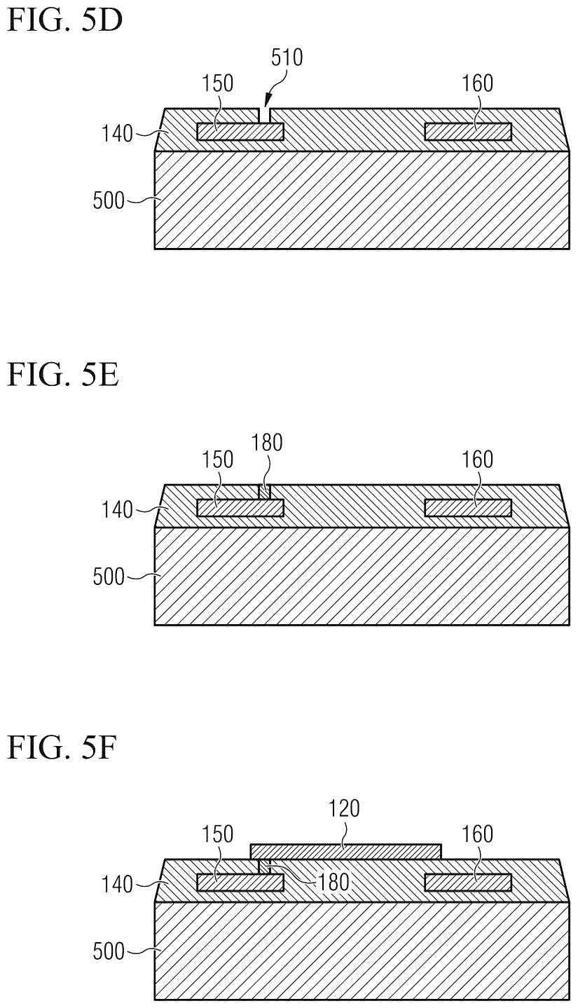

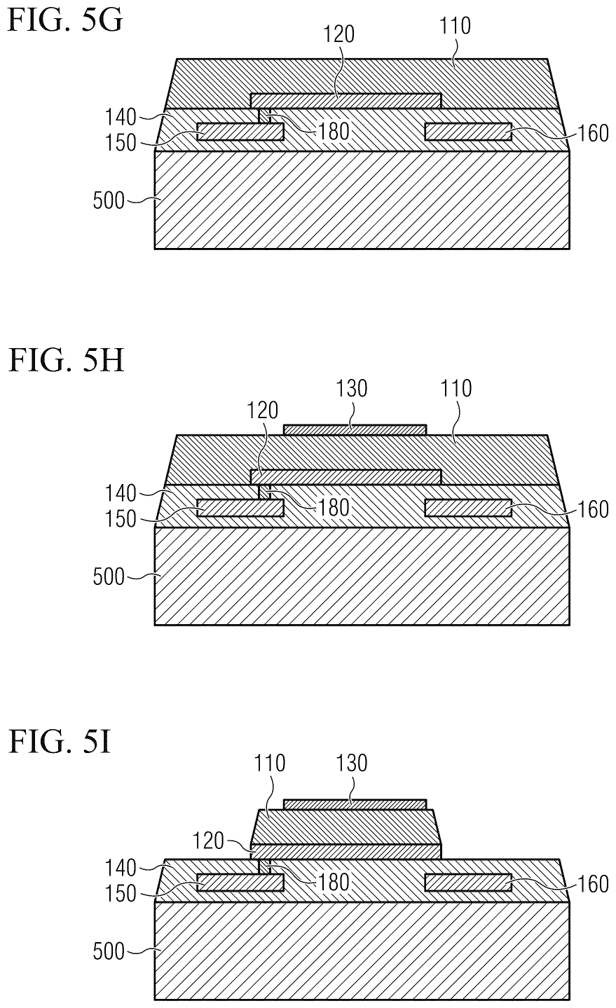

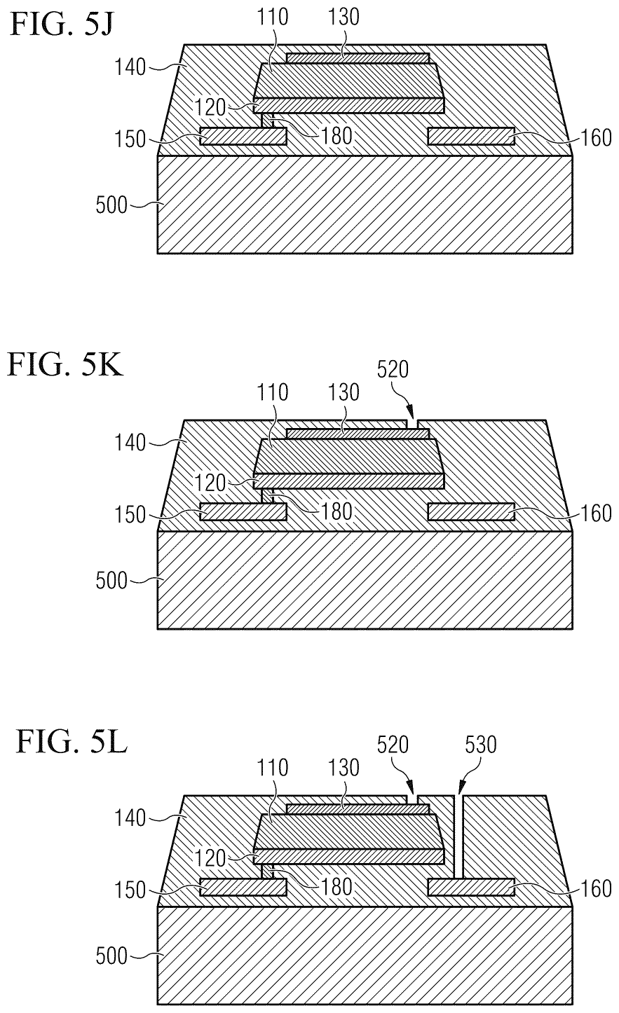

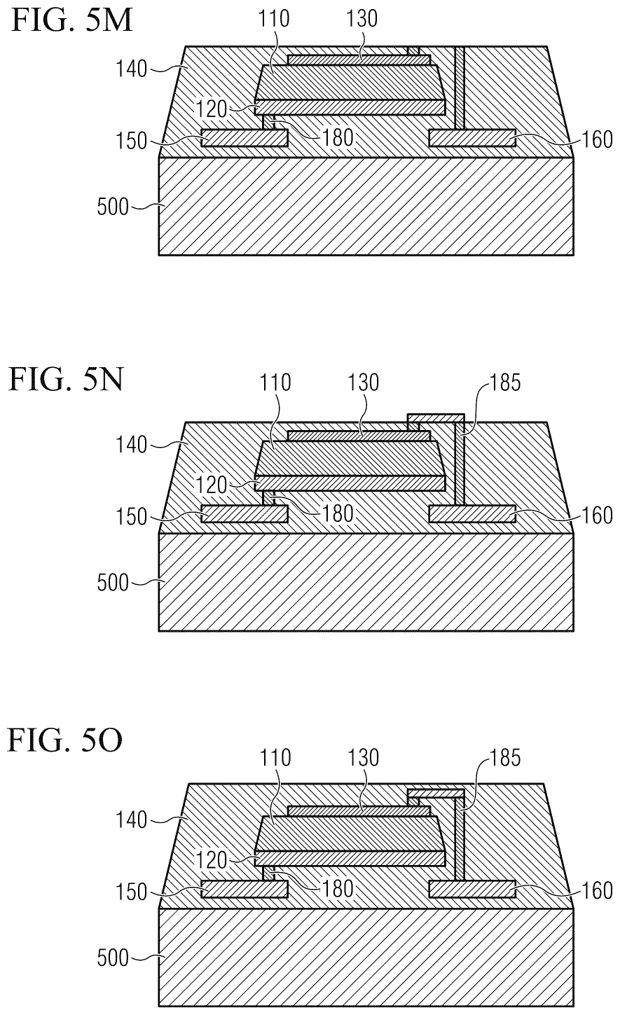

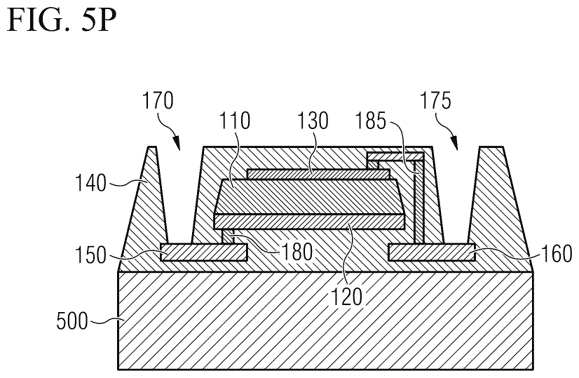

Further details of the method 400 will be apparent from the following description of FIGS. 5A-5P which illustrate the piezoelectric device 100 during various steps of its manufacture.

FIG. 5A illustrates that initially a layer of the dielectric material 140 (e.g., SiO₂ or Si₃N₄) is deposited on a semiconductor substrate 500 (e.g., a silicon substrate).

FIG. 5B illustrates that the first interconnect 150 and the second interconnect 160 are subsequently formed on the layer of the dielectric material 140. For example, a material for the first interconnect 150 and the second interconnect 160 may be deposited on the layer of the dielectric material 140, a light-sensitive chemical (such as a photoresist) may be coated on the material and be structured in accordance with the desired geometry of the first interconnect 150 and the second interconnect 160 by means of photolithography. Undesired parts of material are removed by etching in accordance with the photolithographic structuring to form the first interconnect 150 and the second interconnect 160. Residuals of the material and the light-sensitive chemical may be subsequently removed in a cleaning process.

Then, as illustrated in FIG. 5C), more of the dielectric material 140 is deposited. The surface of the dielectric material 140 is planarized by Chemical Mechanical Polishing (CMP).

An opening (recess) 510 is etched into the dielectric material 140 for the first electrically conductive path 180 between the first electrode 120 and the first interconnect 150 (see FIG. 5D). The opening 510 is filled with electrically conductive material to form a via as the first electrically conductive path 180 (see FIG. 5E). As illustrated in FIG. 5F, the first electrode 120 is subsequently formed on the planar surface of the dielectric material 140 by depositing and structuring corresponding electrically conductive material such as metal(s).

Then the material for the piezoelectric layer 110 is deposited as illustrated in FIG. 5G. For example, a thin film may be deposited for the piezoelectric layer 110. In particular, the material deposited for the piezoelectric layer 110 may comprise (e.g., highly-) doped piezoelectric material such Sc-doped AlN. Subsequently, the second electrode 130 is formed on the piezoelectric layer 110 (see FIG. 5H). The second electrode 130 may be formed analogously to the first electrode 120. After forming the second electrode 130, the material for the piezoelectric layer 110 is etched to obtain the desired geometry of the piezoelectric layer 110 (see FIG. 5I). Dry etch and/or wet etch processes may be used for removing the undesired parts of the deposited material for the piezoelectric layer 110. The undesired parts of material for the piezoelectric layer 110 may, e.g., be removed by etching in accordance with a photolithographic structure coated on the material for the piezoelectric layer 110 (and the second electrode 130) to form the piezoelectric layer 110.

Then, as illustrated in FIG. 5J, more of the dielectric material 140 is deposited. The surface of the dielectric material 140 is planarized by CMP.

Openings (recesses) 520 and 530 extending to the to the second electrode 130 and the second interconnect 160 are etched into the dielectric material 140 for the second electrically conductive path 185 between the second electrode 130 and the second interconnect 160 (see FIGS. 5K and 5L). When forming the openings 520 and 530, the dielectric material 140 is used as an etch stop preventing the etch from reaching the piezoelectric layer 110 at the cost of some loss of dielectric material. The openings 520 and 530 are filled with electrically conductive material (see FIG. 5M) to form vias. Further electrically conductive material connecting the vias is deposited on the dielectric material 140 to form the second electrically conductive path 185 (see FIG. 5N). The structuring of the electrically conductive material connecting the vias may be done analogously to forming the first interconnect 150 and the second interconnect 160.

Then, as illustrated in FIG. 5O, more of the dielectric material 140 is deposited. The surface of the dielectric material 140 is planarized by CMP.

Finally, as illustrated in FIG. 5P, the openings 170 and 175 for accessing the first interconnect 150 and the second interconnect 160 are formed by etching part of the dielectric material 140. Accordingly, the first interconnect 150 and the second interconnect 160 may be electrically contacted via bond wires, etc.

It is to be noted that the process flow for manufacturing the piezoelectric device 100 described above with reference to FIGS. 5A-5P is merely an example. Other or different process steps may be used for manufacturing the piezoelectric device 100 in alternative examples.

### ASPECTS

The aspects described herein may be summarized as follows:

An aspect (e.g., aspect 1) relates to a piezoelectric device, comprising a piezoelectric layer comprising a first surface and a second surface opposing each other, a first electrode formed on the first surface, a second electrode formed on the second surface, a dielectric material enclosing the piezoelectric layer, a first interconnect electrically coupled to the first electrode, and a second interconnect electrically coupled to the second electrode, wherein the first electrode is arranged between the piezoelectric layer and each of the first interconnect and the second interconnect, and wherein the first interconnect and the second interconnect are arranged distant to the first electrode. Thus, the first electrode is arranged between the piezoelectric layer and the first interconnect, and the first electrode is arranged between the piezoelectric layer and the second interconnect.

Another aspect (e.g., aspect 2) relates to a previous aspect (e.g., aspect 1) or to any other aspect, further comprising that the piezoelectric layer is a thin film.

Another aspect (e.g., aspect 3) relates to a previous aspect (e.g., one of the aspects 1 or 2) or to any other aspect, further comprising that a thickness of the piezoelectric layer is at least 0.5 μm, and/or that the thickness of the piezoelectric layer is at maximum 3 μm.

Another aspect (e.g., aspect 4) relates to a previous aspect (e.g., one of the aspects 1 to 3) or to any other aspect, further comprising that the piezoelectric layer comprises a doped piezoelectric material.

Another aspect (e.g., aspect 5) relates to a previous aspect (e.g., aspect 4) or to any other aspect, further comprising that an atomic ratio of dopants in the doped piezoelectric material is at least 20%.

Another aspect (e.g., aspect 6) relates to a previous aspect (e.g., one of the aspects 4 or 5) or to any other aspect, further comprising that the doped piezoelectric material is Scandium-doped Aluminum Nitride.

Another aspect (e.g., aspect 7) relates to a previous aspect (e.g., one of the aspects 1 to 6) or to any other aspect, further comprising a first electrically conductive path formed in the dielectric material between the first electrode and the first interconnect for electrically coupling the first interconnect to the first electrode, and a second electrically conductive path formed in the dielectric material between the second electrode and the second interconnect for electrically coupling the second interconnect to the second electrode.

Another aspect (e.g., aspect 8) relates to a previous aspect (e.g., one of the aspects 1 to 7) or to any other aspect, further comprising that a first opening extends from a surface of the dielectric material to the first interconnect, and that a second opening extends from the surface of the dielectric material to the second interconnect, wherein the second electrode is arranged between the second surface of the piezoelectric layer and the surface of the dielectric material.

Another aspect (e.g., aspect 9) relates to a previous aspect (e.g., aspect 8) or to any other aspect, further comprising that the first opening and the second opening extend laterally offset to the dielectric layer.

Another aspect (e.g., aspect 10) relates to a previous aspect (e.g., one of the aspects 8 or 9) or to any other aspect, further comprising that the first interconnect is accessible via the first opening, and wherein the second interconnect is accessible via the second opening.

Another aspect (e.g., aspect 11) relates to a previous aspect (e.g., one of the aspects 1 to 10) or to any other aspect, further comprising that a vertical distance of the first interconnect to the first electrode is smaller than the vertical distance of the first interconnect to the second electrode, and that the vertical distance of the second interconnect to the first electrode is smaller than the vertical distance of the second interconnect to the second electrode.

Another aspect (e.g., aspect 12) relates to an ultrasonic transducer comprising the piezoelectric device according to a previous aspect (e.g., any one of aspects 1 to 11) or to any other aspect, wherein a recess is formed in the dielectric material such that part of the dielectric material forms a diaphragm embedding the piezoelectric layer.

Another aspect (e.g., aspect 13) relates to a previous aspect (e.g., aspect 12) or to any other aspect, further comprising that the recess is formed distant to the first electrode, wherein the first electrode is arranged between the piezoelectric layer and the recess, and wherein the recess is formed laterally between the first interconnect and the second interconnect.

Another aspect (e.g., aspect 14) relates to a previous aspect (e.g., one of the aspects 12 or 13) or to any other aspect, further comprising that the piezoelectric device is configured to deform the diaphragm based on an electrical signal received at the first and the second interconnect to emit ultrasonic waves, and/or output a respective measurement signal at the first and the second interconnect based on a deformation of the diaphragm caused by received ultrasonic waves.

An aspect (e.g., aspect 15) relates to a micro-electromechanical device comprising a micromirror, and a spring structure supporting the micromirror, wherein the spring structure comprises at least one piezoelectric device according to a previous aspect (e.g., any one of aspects 1 to 11) or to any other aspect.

Another aspect (e.g., aspect 16) relates to a previous aspect (e.g., aspect 15) or to any other aspect, further comprising that the at least one piezoelectric device is configured to deform the spring structure based on an electrical signal received at the first and the second interconnect to deform the spring structure for deflecting the micromirror, and/or output a respective measurement signal at the first and the second interconnect based on a deflection of the micromirror.

An aspect (e.g., aspect 17) relates to a method of forming a piezoelectric device, comprising forming a piezoelectric layer comprising a first surface and a second surface opposing each other, forming a first electrode on the first surface, forming a second electrode on the second surface, forming a dielectric material enclosing the piezoelectric layer, forming a first interconnect electrically coupled to the first electrode, and forming a second interconnect electrically coupled to the second electrode, wherein the first electrode is arranged between piezoelectric layer and each of the first interconnect and the second interconnect, and wherein the first interconnect and the second interconnect are arranged distant to the first electrode.

Another aspect (e.g., aspect 18) relates to a previous aspect (e.g., aspect 17) or to any other aspect, further comprising forming a first electrically conductive path in the dielectric material between the first electrode and the first interconnect for electrically coupling the first interconnect to the first electrode, and forming a second electrically conductive path in the dielectric material between the second electrode and the second interconnect for electrically coupling the second interconnect to the second electrode.

Another aspect (e.g., aspect 19) relates to a previous aspect (e.g., one of the aspects 17 or 18) or to any other aspect, further comprising forming a first opening in the dielectric material, the first opening extending from a surface of the dielectric material to the first interconnect, and forming a second opening in the dielectric material, the second opening extending from the surface of the dielectric material to the second interconnect, wherein the second electrode is arranged between the second surface of the piezoelectric layer and the surface of the dielectric material.

Another aspect (e.g., aspect 20) relates to a previous aspect (e.g., one of the aspects 17 to 19) or to any other aspect, further comprising that forming a piezoelectric layer comprises depositing a doped piezoelectric material, and wherein an atomic ratio of dopants in the doped piezoelectric material is at least 20%.

The aspects and features described in relation to a particular one of the previous aspects may also be combined with one or more of the further aspects to replace an identical or similar feature of that further aspect or to additionally introduce the features into the further aspect.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further aspects, a single step, function, process or operation may include and/or be broken up into several sub-steps, -functions, -processes or -operations.

If some aspects have been described in relation to a device or system, these aspects should also be understood as a description of the corresponding method. For aspect, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate aspect. It should also be noted that although in the claims a dependent claim refers to a particular combination with one or more other claims, other aspects may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A piezoelectric device, comprising:
a piezoelectric layer comprising a first surface and a second surface opposing each other;
a first electrode formed on the first surface;
a second electrode formed on the second surface;
a dielectric material enclosing the piezoelectric layer;
a first interconnect electrically coupled to the first electrode; and
a second interconnect electrically coupled to the second electrode,
wherein the first electrode is arranged between the piezoelectric layer and the first interconnect,
wherein the first electrode is arranged between the piezoelectric layer and the second interconnect, and
wherein the first interconnect and the second interconnect are arranged distant to the first electrode.

2. The piezoelectric device of claim 1, wherein the piezoelectric layer is a thin film.

3. The piezoelectric device of claim 1,
wherein a thickness of the piezoelectric layer is at least 0.5 μm, and
wherein the thickness of the piezoelectric layer is at maximum 3 μm.

4. The piezoelectric device of claim 1, wherein the piezoelectric layer comprises a doped piezoelectric material.

5. The piezoelectric device of claim 4, wherein an atomic ratio of dopants in the doped piezoelectric material is at least 20%.

6. The piezoelectric device of claim 4, wherein the doped piezoelectric material is Scandium-doped Aluminum Nitride.

7. The piezoelectric device of claim 1, further comprising:
a first electrically conductive path formed in the dielectric material between the first electrode and the first interconnect for electrically coupling the first interconnect to the first electrode; and
a second electrically conductive path formed in the dielectric material between the second electrode and the second interconnect for electrically coupling the second interconnect to the second electrode.

8. The piezoelectric device of claim 1,
wherein a first opening extends from a surface of the dielectric material to the first interconnect,
wherein a second opening extends from the surface of the dielectric material to the second interconnect, and
wherein the second electrode is arranged between the second surface of the piezoelectric layer and the surface of the dielectric material.

9. The piezoelectric device of claim 8, wherein the first opening and the second opening extend laterally offset to the dielectric layer.

10. The piezoelectric device of claim 8,
wherein the first interconnect is accessible via the first opening, and
wherein the second interconnect is accessible via the second opening.

11. The piezoelectric device of claim 1,
wherein a vertical distance of the first interconnect to the first electrode is smaller than a vertical distance of the first interconnect to the second electrode, and
wherein a vertical distance of the second interconnect to the first electrode is smaller than a vertical distance of the second interconnect to the second electrode.

12. An ultrasonic transducer, comprising:
a piezoelectric device, comprising:
a piezoelectric layer comprising a first surface and a second surface opposing each other;
a first electrode formed on the first surface;
a second electrode formed on the second surface;
a dielectric material enclosing the piezoelectric laver;
a first interconnect electrically coupled to the first electrode; and
a second interconnect electrically coupled to the second electrode,
wherein the first electrode is arranged between the piezoelectric layer and the first interconnect,
wherein the first electrode is arranged between the piezoelectric layer and the second interconnect,
wherein the first interconnect and the second interconnect are arranged distant to the first electrode, and
wherein a recess is formed in the dielectric material such that part of the dielectric material forms a diaphragm embedding the piezoelectric layer.

13. The ultrasonic transducer of claim 12,
wherein the recess is formed distant to the first electrode,
wherein the first electrode is arranged between the piezoelectric layer and the recess, and
wherein the recess is formed laterally between the first interconnect and the second interconnect.

14. The ultrasonic transducer of claim 12, wherein the piezoelectric device is configured to:
deform the diaphragm based on an electrical signal received at the first interconnect and the second interconnect to emit ultrasonic waves; or
output a respective measurement signal at the first interconnect and the second interconnect based on a deformation of the diaphragm caused by received ultrasonic waves.

15. A micro-electromechanical device, comprising:
a micromirror; and
a spring structure supporting the micromirror, wherein the spring structure comprises at least one piezoelectric device,
wherein each piezoelectric device of the at least one piezoelectric device comprises;
a piezoelectric layer comprising a first surface and a second surface opposing each other;
a first electrode formed on the first surface;
a second electrode formed on the second surface;
a dielectric material enclosing the piezoelectric laver;
a first interconnect electrically coupled to the first electrode; and
a second interconnect electrically coupled to the second electrode,
wherein the first electrode is arranged between the piezoelectric layer and the first interconnect,
wherein the first electrode is arranged between the piezoelectric layer and the second interconnect, and
wherein the first interconnect and the second interconnect are arranged distant to the first electrode.

16. The micro-electromechanical device of claim 15, wherein the at least one piezoelectric device is configured to:
deform the spring structure based on an electrical signal received at the first interconnect and the second interconnect to deform the spring structure for deflecting the micromirror; or
output a respective measurement signal at the first interconnect and the second interconnect based on a deflection of the micromirror.

17. A method of forming a piezoelectric device, comprising:
forming a piezoelectric layer comprising a first surface and a second surface opposing each other;
forming a first electrode on the first surface;
forming a second electrode on the second surface;
forming a dielectric material enclosing the piezoelectric layer;
forming a first interconnect electrically coupled to the first electrode; and
forming a second interconnect electrically coupled to the second electrode,
wherein the first electrode is arranged between piezoelectric layer and the first interconnect,
wherein the first electrode is arranged between the piezoelectric layer and the second interconnect, and
wherein the first interconnect and the second interconnect are arranged distant to the first electrode.

18. The method of claim 17, further comprising:
forming a first electrically conductive path in the dielectric material between the first electrode and the first interconnect for electrically coupling the first interconnect to the first electrode; and
forming a second electrically conductive path in the dielectric material between the second electrode and the second interconnect for electrically coupling the second interconnect to the second electrode.

19. The method of claim 17, further comprising:
forming a first opening in the dielectric material, the first opening extending from a surface of the dielectric material to the first interconnect; and
forming a second opening in the dielectric material, the second opening extending from the surface of the dielectric material to the second interconnect, wherein the second electrode is arranged between the second surface of the piezoelectric layer and the surface of the dielectric material.

20. The method of claim 17,
wherein forming the piezoelectric layer comprises depositing a doped piezoelectric material, and
wherein an atomic ratio of dopants in the doped piezoelectric material is at least 20%.
